(19) United States
(12) Patent Application Publication
(10) Pub. No.: US 2018/0006482 A1
(43) Pub. Date: Jan. 4, 2018

(54) TERMINAL APPARATUS, INPUT APPARATUS, AND POWER CONTROLLING METHOD THEREOF

(71) Applicant: SAMSUNG ELECTRONICS CO., LTD., Suwon-si (KR)

(72) Inventors: Su-hwan JIN, Suwon-si (KR); Dae-yeon YUN, Seoul (KR); Yui-yoon LEE, Suwon-si (KR); Hyun-kyu YUN, Seoul (KR); Moon-pyo HONG, Seoul (KR)

(73) Assignee: SAMSUNG ELECTRONICS CO., LTD., Suwon-si (KR)

(21) Appl. No.: 15/621,579

(22) Filed: Jun. 13, 2017

(30) Foreign Application Priority Data
Jul. 3, 2016 (KR) 10-2016-0083899

(51) Int. Cl. H02J 7/00; G01R 19/14

(52) U.S. Cl. CPC H02J 7/0068; H02J 7/0086; G01R 19/14; H02J 7/0021; H02J 7/007

(57) ABSTRACT

A terminal apparatus includes a battery configured to supply operation power for the terminal apparatus and be rechargeable, a regulator configured to regulate and output the operation power supplied from the battery to have a predetermined level, a connector configured to include a plurality of terminal pins and receive charging power for the battery from an external charging source through the plurality of terminal pins, and a connector cap configured to couple with the connector and have a pattern for electrically connecting a first pin and a second pin among the plurality of terminal pins while coupling with the connector to prevent electric current of the battery from being consumed. A product including the terminal apparatus is released in a state that the cap for electric connection between the terminal pins is coupled to the connector, preventing a standby electric current of the battery from being consumed during distribution.

### CROSS-REFERENCE TO RELATED APPLICATIONS

This application claims the priority benefit of Korean Patent Application No. 10-2016-0083899, filed on Jul. 3, 2016, in the Korean Intellectual Property Office, the disclosure of which is incorporated herein by reference in its entirety.

### BACKGROUND

### 1. Field

Apparatuses and methods with respect to the exemplary embodiments disclosed herein relate to a terminal apparatus, an input apparatus and a power controlling method thereof, and more particularly to a terminal apparatus and an input apparatus, which receive power from a rechargeable battery by an external charging source, and a power controlling method thereof.

### 2. Description of the Related Art

With development of electronics, various types of electronic products have been being developed and propagated. For example, not only a smart phone and a tablet computer but also various terminal apparatuses including a smart watch, a smart band, a wireless headset and the like wearable device, an input apparatus or the like for transmitting a control command to other devices such as a television, and the like have been more and more widely used.

In case of a smart phone, a wearable device, an input apparatus and the like terminal apparatus, they are generally launched as a product with a built-in battery, i.e. with a secondary battery to be charged by an external charging source.

The products with the built-in battery are released in a deep sleep mode where power is supplied to only minimum blocks for basically operating a main processor. Further, the products are generally released with the secondary battery charged to about 60% of its total capacity. Due to transportation regulations, the charged percentage at the release is being lowered.

Therefore, the secondary battery may be fully discharged if the product is neglected for a long time during distribution. If the secondary battery is fully discharged, it may be inconvenient for a consumer since the consumer has to charge the product directly after purchase. Besides, if the secondary battery is fully discharged, it may incur a shortened life of the secondary battery or damage of the product.

### SUMMARY

Additional aspects and/or advantages will be set forth in part in the description which follows and, in part, will be apparent from the description, or may be learned by practice of the disclosure.

In accordance with an exemplary embodiment, there is provided a terminal apparatus including: a battery configured to supply operation power for the terminal apparatus and be rechargeable, a regulator configured to regulate and output the operation power supplied from the battery to have a predetermined level, a connector configured to include a plurality of terminal pins and receive charging power for the battery from an external charging source through the plurality of terminal pins, and a connector cap configured to couple with the connector and have a pattern for electrically connecting a first pin and a second pin among the plurality of terminal pins while coupling with the connector to prevent an electric current of the battery from being consumed. Thus, a product is released in a state that the cap for electric connection between the terminal pins is coupled to the connector, thereby preventing a standby electric current of the battery from being consumed during distribution.

The first pin and the second pin may be electrically connected as the connector cap couples with the connector, and thus the regulator for receiving the operation power from the battery becomes inactivated. Thus, the regulator for regulating and outputting the operation power received from the battery becomes inactivated, thereby having an effect on cutting off the operation power not to consume a standby electric current.

The terminal apparatus may further include a processor configured to receive the operation power from the battery through the regulator, the regulator may be provided in between the battery and the processor, and the inactivated regulator may cut off the operation power not to be supplied to the processor. Thus, the supply of the operation power to the processor for carrying out operations is easily cut off in accordance with activation/inactivation of the regulator.

The regulator may become activated when the first pin and the second pin are electrically disconnected in response to removal of the connector cap from the connector, and the operation power may be supplied to at least a part of the processor through the activated regulator. Thus, a consumer can directly use the terminal apparatus by just removing the cap from the connector after making a purchase of the terminal apparatus.

The processor may include a switching block to be turned on in response to a user's input and a main block to perform operations, and the operation power may be supplied to the switching block in response to the activation of the regulator. Thus, the operation power is supplied to the terminal apparatus in response to a use's button control, and it is thus possible to normally use the terminal apparatus.

The first pin may be connected to the battery, and the second pin may be connected to an enable terminal of the regulator. Thus, the regulator is activated/inactivated by a simple method of applying a high or low signal to the enable terminal.

The connector may include a universal serial bus (USB) connector, and the connector cap may include a coupling hole or a coupling projection to be inserted in and engaged with the USB connector. Thus, an inventive concept may be applicable to a product having the widespread USB connector, and the cap is prevented from being separated during distribution.

The plurality of terminal pins may include a power pin and a ground pin to receive the charging power from the external charging source, and the first pin and the second pin not used in receiving the charging power may be electrically connected by the pattern. Thus, it is possible to utilize the pins not used in charging are utilized.

In accordance with another exemplary embodiment, there is provided a power controlling method of a terminal apparatus that receives operation power from a rechargeable battery, the method including: sensing that a connector cap having a pattern for electrically connecting a first pin and a second pin among a plurality of terminal pins provided in a connector is coupled to the connector for receiving charging power for the battery from an external charging source through the plurality of terminal pins, and inactivating a regulator for regulating and outputting the operation power supplied from the battery to have a predetermined level as the first pin and the second pin are electrically connected in response to coupling between the connector and the connector cap. Thus, a product is released in a state that the cap for electric connection between the terminal pins is coupled to the connector, thereby preventing a standby electric current of the battery from being consumed during distribution.

The regulator may be provided in between the battery and a processor, and the inactivated regulator may cut off the operation power not to be supplied to the processor. Thus, the regulator for regulating and outputting the operation power received from the battery becomes inactivated, thereby having an effect on cutting off the operation power not to consume a standby electric current.

The method may further include: sensing that the connector cap is removed from the connector, activating the regulator as the first pin and the second pin are electrically disconnected in response to the removal of the connector cap, and supplying the operation power to at least a part of the processor through the activated regulator. Thus, a consumer can directly use the terminal apparatus by just removing the cap from the connector after making a purchase of the terminal apparatus.

In accordance with another exemplary embodiment, there is provided an input apparatus for a display apparatus, the input apparatus including: a battery configured to supply operation power for the terminal apparatus and be rechargeable, a regulator configured to regulate and output the operation power supplied from the battery to have a predetermined level, a connector configured to include a plurality of terminal pins and receive charging power for the battery from an external charging source through the plurality of terminal pins, and a connector cap configured to couple with the connector and have a pattern for electrically connecting a first pin and a second pin among the plurality of terminal pins while coupling with the connector to prevent an electric current of the battery from being consumed. Thus, a product is released in a state that the cap for electric connection between the terminal pins is coupled to the connector, thereby preventing a standby electric current of the battery from being consumed during distribution.

The first pin and the second pin may be electrically connected as the connector cap couples with the connector, and thus the regulator for receiving the operation power from the battery may become inactivated. Thus, the regulator for regulating and outputting the operation power received from the battery becomes inactivated, thereby having an effect on cutting off the operation power not to consume a standby electric current.

The input apparatus may further include a processor configured to receive the operation power from the battery through the regulator, the regulator may be provided in between the battery and the processor, and the inactivated regulator may cut off the operation power not to be supplied to the processor. Thus, the supply of the operation power to the processor for carrying out operations is easily cut off in accordance with activation/inactivation of the regulator.

The regulator may become activated when the first pin and the second pin are electrically disconnected in response to removal of the connector cap from the connector, and the operation power may be supplied to at least a part of the processor through the activated regulator. Thus, a consumer can directly use the terminal apparatus by just removing the cap from the connector after making a purchase of the terminal apparatus.

The first pin may be connected to the battery, and the second pin is connected to an enable terminal of the regulator. Thus, the regulator is activated/inactivated by a simple method of applying a high or low signal to the enable terminal.

The connector may include a universal serial bus (USB) connector, and the connector cap may include a coupling hole or a coupling projection to be inserted in and engaged with the USB connector. Thus, an inventive concept may be applicable to a product having the widespread USB connector, and the cap is prevented from being separated during distribution.

The plurality of terminal pins may include a power pin and a ground pin to receive the charging power from the external charging source, and the first pin and the second pin not used in receiving the charging power may be electrically connected by the pattern. Thus, it is possible to utilize the pins not used in charging are utilized.

### BRIEF DESCRIPTION OF THE DRAWINGS

The above and/or other aspects will become apparent and more readily appreciated from the following description of exemplary embodiments, taken in conjunction with the accompanying drawings, in which:

FIG. 1 is a block diagram of a terminal apparatus according to an exemplary embodiment;

FIG. 2 is a circuit diagram for explaining that a power supply supplies charging power and operation power in the terminal apparatus according to an exemplary embodiment;

FIG. 3 illustrates a connector of the terminal apparatus according to an exemplary embodiment and a connector cap to be coupled to the connector;

FIG. 4 is a view for explaining operations when the connector cap is coupled to the connector in the circuit diagram of FIG. 2;

FIG. 5 is a circuit diagram for explaining that a power supply supplies charging power and operation power in a terminal apparatus according to another exemplary embodiment; and

FIG. 6 and FIG. 7 are flowcharts of a power controlling method of the terminal apparatus according to exemplary embodiments.

### DETAILED DESCRIPTION

Below, exemplary embodiments will be described with reference to accompanying drawings to such an extent as to be easily realized by a person having an ordinary knowledge in the art. One or more inventive concepts of the disclosure are not limited to the embodiments set forth herein, and may be materialized variously.

Terms to be used in the following descriptions will be selected as general terms currently used as widely as possible taking functions of elements into account, but may be varied depending on intent of those skilled in the art, precedents, the advent of new technology, etc. In particular, there may be a term voluntarily selected by the applicant. In this case, the meaning of the term will be explained in detail through the relevant detailed descriptions. Therefore, the terms set forth herein have to be read in light of its meaning and content throughout the following descriptions rather than naming.

In the following descriptions, terms such as “include” or “have” refer to presence of features, numbers, steps, operations, elements or combination thereof, and do not exclude presence or addition of one or more other features, numbers, steps, operations, elements or combination thereof.

A “portion” set forth herein refers to software or hardware such as FPGA or ASIC, and performs certain roles. However, the meaning of the “portion” is not limited to software or hardware. The “portion” may be configured to be present in a storage medium for addressing or may be configured to reproduce one or more processors. For example, the “portion” includes software elements, object-oriented software elements, class elements, task elements and the like elements, and processes, functions, attributes, procedures, subroutines, segments of a program code, drivers, firmware, a microcode, a circuit, data, a database, data structures, tables, arrays and variables. The function provided in the elements and the “portions” may be carried out by combining fewer elements and “portions” or may be subdivided by additional elements and “portions”.

For clarity, elements not directly related to the elements of the exemplary embodiment may be omitted. Reference will now be made in detail to example embodiments which are illustrated in the accompanying drawings, like reference numerals refer to like elements throughout.

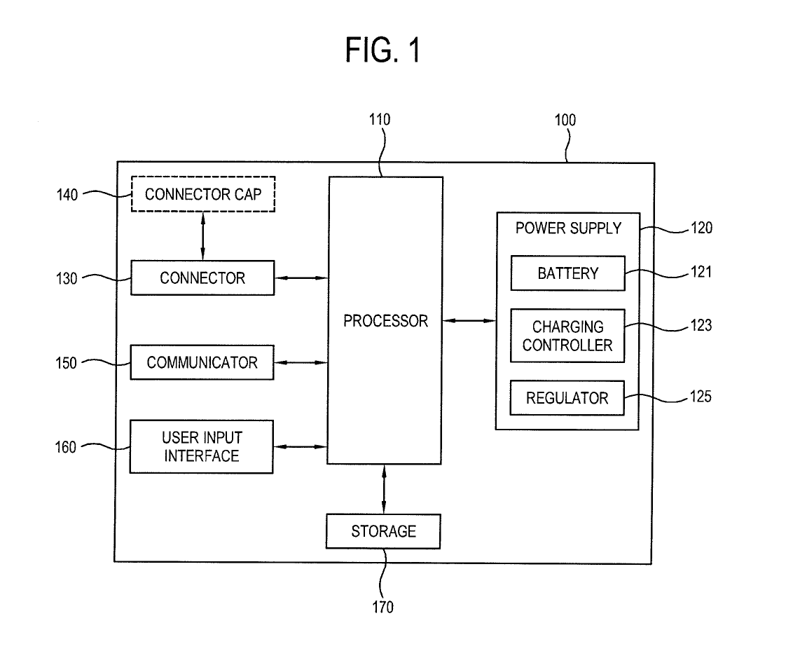

FIG. 1 is a block diagram of a terminal apparatus 100 according to an exemplary embodiment.

The terminal apparatus 100 according to an exemplary embodiment refers to an apparatus with a built-in battery, which may include a battery 121 for supplying operation power. Here, the battery 121 may be achieved by a secondary battery (or a secondary cell or a rechargeable battery) rechargeable by an external charging source. The terminal apparatus 100 may include a connector 130 for connecting with the external charging source and receiving charging power.

In this exemplary embodiment, the terminal apparatus 100 refers to an apparatus that wirelessly connects with other apparatuses through a communicator 150 to be described later and is capable of transmitting and receiving data and/or a control signal.

In the terminal apparatus 100 according to this exemplary embodiment, a user input interface 160 including at least one button may be defined. The user input interface 160 transmits various preset control commands or information to the processor 110 in response to a user's input.

According to an exemplary embodiment, the terminal apparatus 100 may refer to an input apparatus including a remote controller (or a remote control unit) for transmitting a control command to other apparatuses such as a television (TV, e.g. a smart TV).

According to another exemplary embodiment, the terminal apparatus 100 may refer to a wearable apparatus (hereinafter, referred to as a digital accessory, a smart accessory, or an Appcessory) such as a smart watch, a smart band, a wireless headset (e.g. a Bluetooth headset) and the like to be worn on a user's body.

According to still another exemplary embodiment, the terminal apparatus 100 may refer to a digital apparatus such as a smart phone, a tablet computer or the like smart pad, a personal digital assistant (PDA), etc., or an electronic apparatus such as a mobile television to be driven by a battery.

According to still another exemplary embodiment, the terminal apparatus 100 may refer to various kinds of electronic apparatuses provided as things or smart things operating based on technology of Internet of Things (loT), such as healthcare, telemetering, a smart home, a smart car, etc. To this end, the terminal apparatus 100 may include sensors for carrying out operations of each apparatus and sensing surrounding environments

Below, the terminal apparatus 100 will be described with reference to FIG. 1.

As shown in FIG. 1, the terminal apparatus 100 according to an exemplary embodiment may include the processor 110, a power supply 120, a connector 130 and a connector cap 140.

The processor 110 may include a main block (not shown) for operations of the terminal apparatus 100. The processor 110 may perform various functions corresponding to the kinds of terminal apparatus 100.

According to an exemplary embodiment, the processor 110 may include at least one universal processor such as an application processor (AP) and a central processing unit (CPU), a microcomputer (MICOM), and carries out various operations of the terminal apparatus 100 by for example loading a corresponding program to a random access memory (RAM) in accordance with a predetermined algorithm stored in a read only memory (ROM) and executing the program.

The processor 110 may include a single core, a dual core, a triple core, a quad core and other multiple cores. Here, the processor 110 may be achieved by a plurality of processors, for example, a main processor and a sub processor. The sub processor is configured to operate in a standby mode (hereinafter, also referred to as a sleep mode) where only standby power is supplied but the terminal apparatus 100 does not operate).

Further, the processor 110 may additionally include a graphic processing unit (GPU, not shown). For example, the processor 110 may be given in the form of a system on chip (SoC) where the core (not shown) and the GPU (not shown) are combined.

The processor 110, the ROM and the RAM may be connected to one another through an internal bus. The ROM and the RAM may be involved in the storage 170.

According to another exemplary embodiment, the processor 110 may include a processor, i.e. an integrated circuit dedicated for performing a predetermined function in accordance with the kinds of the terminal apparatus 100. For example, the processor 110 may be achieved by a radio frequency integrated circuit (RF IC), various sensor ICs, etc.

The power supply 120 is charged with the charging power received from the external charging source and supplies operation power for the terminal apparatus 100. To this end, the power supply 120 may include a battery 121, a charging controller 123 and a regulator 125 as shown in FIG. 1.

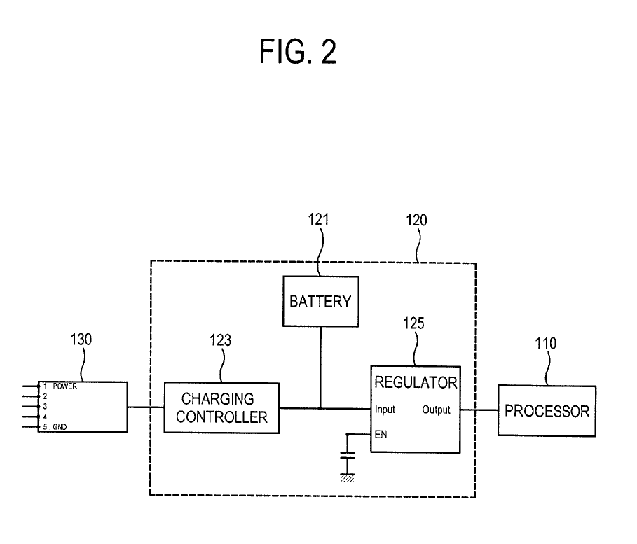

FIG. 2 is a circuit diagram for explaining that the power supply 120 supplies charging power and operation power in the terminal apparatus 100 according to an exemplary embodiment.

The battery 121 may include a lithium polymer battery, a lithium ion battery, a lithium sulfur battery, a nickel cadmium battery, a nickel hydrogen battery, etc. classified according to charging materials, as a secondary battery rechargeable to be semi-permanently used. The battery 121 may be the secondary battery that can receive a charging voltage of a predetermined range, for example, 3V to 4.3V.

The terminal apparatus 100 according to an exemplary embodiment may include one battery 121 as the power supply 120. However, the one or more inventive concepts according to the disclosure are not limited to this exemplary embodiment. Alternatively, the terminal apparatus 100 may include two or more batteries.

The charging controller 123 controls the battery 121 to be charged with the charging power supplied from the external charging source (not shown) through the connector 130.

The charging controller 123 controls the battery 121 to be charged with a direct current (DC) voltage having a predetermined level.

According to an exemplary embodiment, the charging controller 123 may include an alternating current (AC)-DC converter for converting an AC voltage received from the external charging source into the DC voltage, so that the DC voltage having a predetermined level can be supplied to the battery 121, thereby charging the battery 121. For example, the charging controller 123 may receive power of 5V from the external charging source and supply the power of a voltage range (e.g. 3V to 4.3V) allowable in the battery 121. Further, the charging controller 123 may prevent the battery 121 from being overcharged or undercharged.

According to an exemplary embodiment, the charging controller 123 may be achieved by a charger IC as a chip designated for charging control of the battery.

The regulator 125 is provided in between the battery 121 and the processor 110, and regulates the operation power from the battery 121 into a predetermined level to be supplied to the terminal apparatus 100. FIG. 2 illustrates an example that the operation power is supplied to the processor 110. Besides, the operation power of the battery 121 may be supplied to other elements (e.g. the communicator 150, etc.) of the terminal apparatus 100 as well as the processor 110 through the regulator 125.

The regulator 125 according to an exemplary embodiment may be either of a buck converter (hereinafter, also referred to as a buck converter IC or a buck IC) for decreasing an output voltage or a boost converter (hereinafter, also referred to as a boost converter IC or a bust IC) for increasing an output voltage.

According to this exemplary embodiment, the regulator 125 may be achieved by the buck IC for decreasing a voltage of 4.2V received from the battery 121 into a voltage of 3.3V.

As shown in FIG. 2, the regulator 125 achieved by the IC may include an input terminal, an output terminal, and an enable terminal EN (hereinafter, also referred to as an enable pin).

According to an exemplary embodiment, the regulator 125 is activated or inactivated in response to a high/low signal for determining whether to supply power to the enable terminal EN.

For example, if the high signal is applied to the enable terminal, the regulator 125 may become disabled (hereinafter, also referred to as an inactive or off state). On the other hand, if the low signal is applied to the enable terminal, the regulator 125 may become enabled (hereinafter, also referred to as an active or on state). In this case, the low signal is applied to the enable terminal in the circuit diagram of FIG. 2, and thus the regulator becomes enabled, i.e. activated.

The operation (activation) of the regulator 125 determined according to whether the high or low signal applied to the enable terminal is varied depending on the kinds of IC. In other words, there are no limits to settings where the regulator 125 has to be disabled when the high signal is applied to the enable terminal.

Alternatively, the terminal apparatus 100 according to another exemplary embodiment may employ the regulator 125 set to be enabled in response to the high signal and disabled in response to the low signal. In this case, the terminal apparatus 100 may further include an element (e.g. an inverter or the like) for inverting the signal applied to the enable terminal.

The connector 130 may be used as an interface for connecting the terminal apparatus 100 and the external charging source (i.e. the power source). The terminal apparatus 100 receives the charging power for charging the battery 121 through a cable connected to the connector 130, and charges the battery 121 under control of the charging controller 123.

According to an exemplary embodiment, the terminal apparatus 100 may connect with other apparatuses through the cable connected to the connector 130. Here, other apparatuses may include a laptop or desktop computer.

The connector 130 may receive the charging power from the computer through the cable.

Alternatively, the terminal apparatus 100 may transmit data stored in the storage 170 to other apparatuses through the cable connected to the connector 130, or receive data from other apparatuses.

In the terminal apparatus 100 according to an exemplary embodiment, the connector 130 may include a plurality of terminal pins, and receives the charging power for charging the battery from the external charging source through the plurality of terminal pins.

According to an exemplary embodiment, the connector 130 may include a universal serial bus (USB) connector (hereinafter, referred to as a USB port), and receives the charging power through a power pin POWER and a ground pin GND among a plurality of terminal pins as shown in FIG. 2.

FIG. 2 and FIG. 3 to FIG. 5 illustrate an example that the connector 130 according to an exemplary embodiment is the USB connector having five terminal pins, but this example is not construed as limiting the one or more inventive concepts according to the disclosure. Alternatively, the connector 130 may be the USB connector having four or eight terminal pins, and may be compatible with USB 2.0, 3.0, 3.1, etc. according to various versions or types. Alternatively, the connector 130 may be not the USB connector but a cable connector that complies with another standard (e.g. a high definition multimedia interface (HDMI) or the like).

It will be easily understood for a person having an ordinary skill in the art that the connector 130 provided in the terminal apparatus 100 is variously achieved in accordance with the kinds, performances or structures of the terminal apparatus 100.

The connector 130 may be coupled with a connector cap 140.

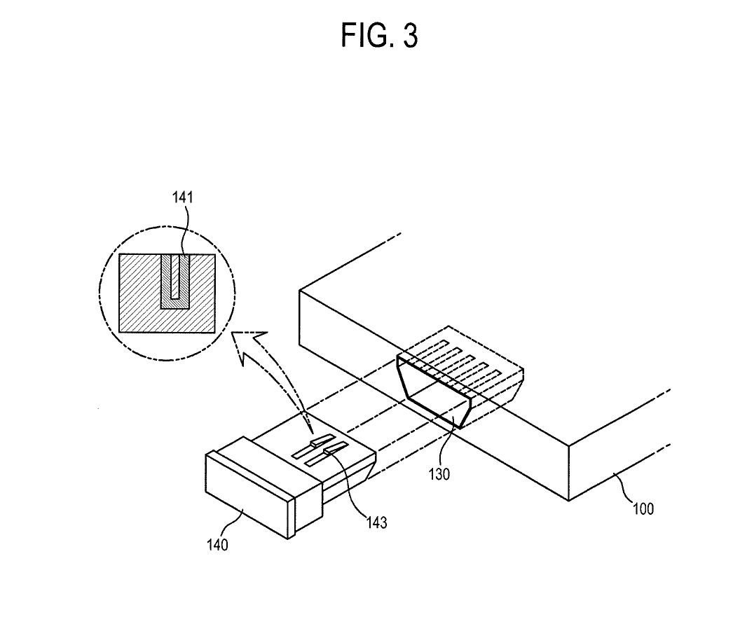

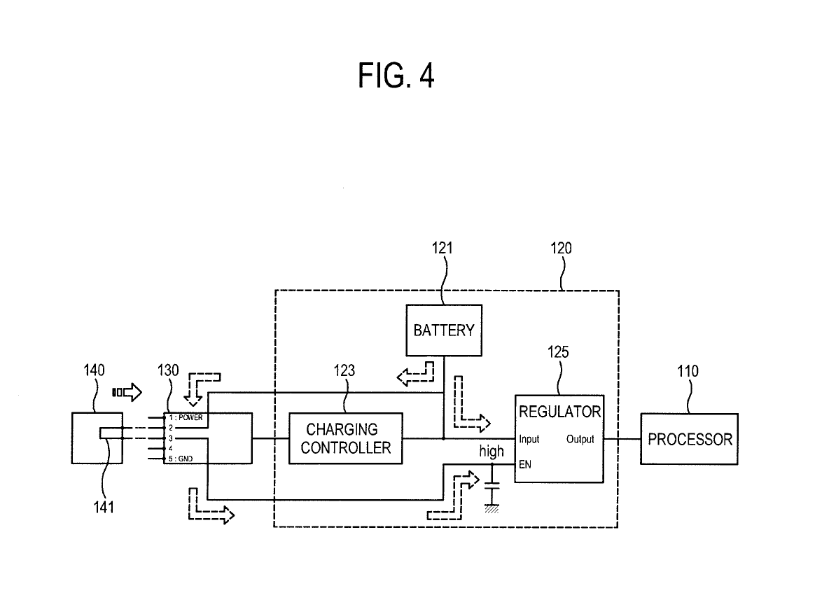

FIG. 3 illustrates the connector 130 of the terminal apparatus 100 according to an exemplary embodiment and a connector cap 140 to be coupled to the connector 130, and FIG. 4 is a view for explaining operations when the connector cap 140 is coupled to the connector 130 in the circuit diagram of FIG. 2.

As shown in FIG. 3, the connector cap 140 may have a structure to be inserted in the connector 130.

According to an exemplary embodiment, the connector cap 140 may be formed with one or more coupling holes or projections 143 to be engaged with the connector 130, and the connector 130 may be internally formed with the coupling projections or holes corresponding to the coupling hole.

The connector cap 140 may be internally formed with a pattern 141 for electrically connecting a first pin and a second pin among the plurality of terminal pins of the connector 130. The pattern 141 may be made of a conductive material and shaped like a line.

The first pin and the second pin exclude the power pin and the ground pin used in receiving the charging power for the battery 121.

Referring to FIG. 2 to FIG. 4, the USB connector 130 including five pins as the plurality of terminal pins employs the power pin (No. 1) and the ground pin (No. 5) to receive the charging power. FIG. 3 and FIG. 4 illustrate an example that two pins (e.g. pin Nos. 2 and 3) among second to fourth pins not used in receiving the charging power are electrically connected by the pattern 141.

When the cap 140 formed with the pattern 141 is coupled to the connector 130, the pins (Nos. 2 and 3) of the connector 130 are electrically connected by the pattern 141 as shown in FIG. 4.

Therefore, the circuit of FIG. 4 forms a kind of closed circuit, and completes a path for signal transmission. In the completed path for the signal transmission, two pins (i.e. pin Nos. 2 and 3) are respectively connected to a battery line and a regulator line. Through this signal transmission path, the operation power of the battery 121 is supplied to the enable terminal EN of the regulator 125 through the connector 130 and the connector cap 140, and thus the enable terminal becomes high. Thus, the regulator 125 is set to be inactivated, i.e. disabled.

As the regulator 125 becomes inactivated, the operation power of the battery 121 supplied through the regulator 125 is cut off from the processor 110.

The following Table 1 shows the states of the enable terminal and the corresponding operation states of the regulator in accordance with whether the connector cap 140 according to an exemplary embodiment is coupled or removed.

TABLE 1

| | State of enable | State of |
|---|---|---|
| | terminal | regulator |
| Connector cap | High | Disable |
| coupled | | |
| Connector cap | GND | Enable |
| removed | | |

When the connector cap 140 is removed from the connector 130, the second pin and the third pin of the connector 130 are electrically disconnected as shown in FIG. 2, and the low signal is applied to the enable terminal EN of the regulator 125, thereby making the enable terminal EN be in the ground state GND as shown in Table 1. Then, the regulator 125 is set to be activated, i.e. enabled.

As described above, if the regulator 125 provided in between the battery 121 and the processor 110 is converted from the disable state to the enable state, at least some blocks of the processor 110 in the terminal apparatus 100 can receive power.

The foregoing terminal apparatus 100 with the built-in battery according to an exemplary embodiment is released in a deep sleep mode where power is supplied to only some blocks for minimum basic operations of the processor 110. Further, due to transportation regulations, the charged percentage of the battery 121 at the release is 60% or less of its total capacity.

Therefore, while the terminal apparatus 100 is being distributed after the release, some blocks of the processor 110 unavoidably consume standby power (e.g. dozens of uA) in real time. For example, if the terminal apparatus 100 employs the battery 121 having a capacity of 250 mAh and consumes a hot standby current of 30 uA, the battery 121 has a charged capacity of about 150 mAh at the release and is fully discharged after about 208 days. Further, this terminal apparatus 100 is neglected in stock for a long time, the battery 121 and/or the terminal apparatus 100 may be damaged.

With this configuration, the terminal apparatus 100 according to an exemplary embodiment is released with the connector cap 140 coupled to the connector 130 in a manufacture stage. Therefore, the regulator 125 is inactivated and the power is thus prevented from being supplied to the whole of the posterior processor 110. Accordingly, the processor 110 does not consume the standby current during a distribution process of a product.

A user, i.e. a purchaser of the terminal apparatus 100 removes the cap 140 coupled to the connector 130 after making a purchase of the product, and thus activates the regulator 125, thereby supplying the operation power from the battery 121 to some blocks of the processor 110 being in a deep sleep mode. Here, the battery 121 of the terminal apparatus 100 has the same charged capacity as the capacity at (i.e. about 150 mAh) at the release time, and therefore a user can directly use the terminal apparatus 100 without separate charging.

Referring to FIG. 1, the terminal apparatus 100 according to an exemplary embodiment further may include the communicator 150, the user input interface 160 and the storage 170.

A communicator 150 may include at least one of a wireless local area network (LAN) unit and a short-range communicator.

The wireless LAN unit may wirelessly connect with an access point (AP) in a place where the AP is installed, under control of the processor 110. The wireless LAN unit supports wireless LAN standards (IEEE 802.11x) of institute of electrical and electronics engineers (IEEE). The short-range communicator may be provide to support short-range wireless communication between other apparatus without using the access point (AP) under control of the processor 110.

The short-range communication may include at least one of Bluetooth, Bluetooth low energy, infrared data association (IrDA), wireless fidelity (Wi-Fi), Wi-Fi Direct, Zigbee, ultra-wideband (UWB), near field communication (NFC), etc.

According to an exemplary embodiment, the terminal apparatus 100 may be connected to the display apparatus as a target to be remotely controlled through the communicator 150 if the terminal apparatus 100 is an input apparatus of a display apparatus such as a television, i.e. if the terminal apparatus 100 is a remote controller.

According to another exemplary embodiment, if the terminal apparatus 100 is a wearable apparatus such as a smart watch, a smart band, a wireless headset, etc., the terminal apparatus 100 may be connected to another apparatus (e.g. a user's smart phone) through the communicator 150.

According to still another exemplary embodiment, if the terminal apparatus 100 is a smart phone, the communicator 150 may further include a mobile communicator. The mobile communicator may connect with other apparatuses by mobile communication through one or at least two antennas (not shown) under control of the processor 110. The mobile communicator transmits and receives a wireless signal for a voice call, a video call, a short message service, a multimedia messaging service and data communication to and from a cellular phone, a smart phone, a tablet computer or another terminal apparatus (i.e. a portable apparatus) having a phone number connectable with the terminal apparatus 100. The wireless signal is transmitted from the mobile communicator to a called party through long term evolution (LTE), 3G, 4G and the like mobile communication network.

The user input interface 160 receives a user's input and may include one or at least two buttons.

According to an exemplary embodiment, if the terminal apparatus 100 is an input apparatus such as a remote controller, the button may include a channel key, a volume key, a numeral key, a menu key, etc. Further, the terminal apparatus 100 achieved by the input apparatus may include at least one of a touch sensing portion for receiving a user's touch input and a motion sensing portion for sensing a motion of the input apparatus, i.e. sensing its own motion. The touch sensing portion may include a touch sensor, i.e. a touch pad, and the motion sensing portion may include at least one position sensor, i.e. a gyro sensor, an angular speed sensor, a geomagnetic sensor, etc.

According to another exemplary embodiment, if the terminal apparatus 100 is a wearable apparatus, the user input interface 160 may include a button for receiving a power-on command for the terminal apparatus 100 from a user. Here, the terminal apparatus 100 may have a separate power button corresponding to the power-on command, or may be powered on if any button is controlled while the terminal apparatus 100 is being turned off.

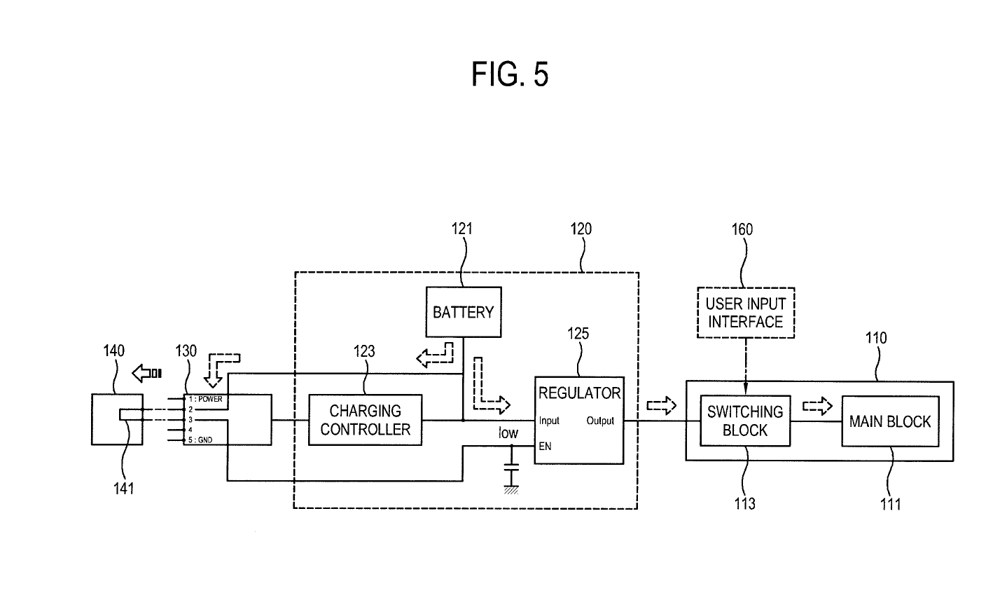

FIG. 5 is a circuit diagram for explaining that the power supply 120 supplies charging power and operation power in the terminal apparatus 100 according to another exemplary embodiment.

As compared with the exemplary embodiment shown in FIG. 2 and FIG. 4, this exemplary embodiment shown in FIG. 5 is characterized in that the processor 110 may include a main block 111 and a switching block 113. Therefore, other elements in this exemplary embodiment but the main block 111 and the switching block 113 are represented with the same numerals and names as those of the foregoing exemplary embodiment, and repetitive descriptions thereof will be avoided as necessary.

The main block 111 may perform various functions in accordance with the kinds of terminal apparatus 100.

As shown in FIG. 5, the switching block 113 may include a switch to be turned on in response to a user's input using the user input interface 160 (e.g. a power button).

The terminal apparatus 100 in this exemplary embodiment shown in FIG. 5 is set to supply power to the switching block 113 of the processor 110 in a deep sleep mode at release. Further, the terminal apparatus 100 is switched over to a normal mode to supply the operation power to the main block 111 if the switching block 113 is turned on in response to the first input of a user who makes a purchase of the terminal apparatus 100.

Like the terminal apparatus 100 according to the foregoing exemplary embodiment, the terminal apparatus 100 in this exemplary embodiment is released with the connector cap 140 coupled to the connector 130 in a manufacture stage. Therefore, the regulator 125 is inactivated and the power is thus prevented from being supplied to the whole of the posterior processor 110 in spite of the deep sleep mode. Accordingly, some blocks of the processor 110 such as the switching block 113 cannot consume any standby current during a distribution process of a product.

As shown in FIG. 5, a user, i.e. a purchaser of the terminal apparatus 100 removes the cap 140 coupled to the connector 130 in accordance with a product guide after making a purchase of the product. Thus, the regulator 125 becomes activated, thereby supplying the operation power from the battery 121 to the switching block 113 of the processor 110. Here, the battery 121 of the terminal apparatus 100 has the same charged capacity as the capacity at (i.e. about 150 mAh) at the release time, and therefore a user can directly use the terminal apparatus 100 without separate charging.

According to still another exemplary embodiment, the terminal apparatus 100 may be achieved by a smart phone. In even this case, the circuit diagram of FIG. 5 may be applied to the terminal apparatus 100 of the smart phone.

If the terminal apparatus 100 is a smart phone, the user input interface 160 may include at least one of a menu button, a home button and a back button provided in a front lower portion thereof. Further, the button may include a power/lock and/or volume buttons in a lateral edge portion thereof. As above, the buttons of the terminal apparatus 100 according to this exemplary embodiment may be achieved by not a physical button but a touch button provided on a touch screen. In this case, the button may be displayed as a text or an icon on the touch screen. To this end, the terminal apparatus 100 further may include a display (not shown) including the touch screen. According to still another exemplary embodiment, the user input interface 160 of the terminal apparatus 100 may include a microphone for receiving an audio signal.

By the way, it will be easily understood for a person having ordinary knowledge in the art that the physical buttons may be excluded from the terminal apparatus 100 in accordance with the performance or structure of the terminal apparatus 100.

According to still another exemplary embodiment, the terminal apparatus 100 may further include at least one sensor for detecting its own state. For example, the sensor may include at least one of a proximity sensor, an illuminance sensor, a posture sensor, a gravity sensor and an altimeter. The at least one sensor senses the state of the terminal apparatus 100, generates a signal corresponding to the sensed state, and transmits the generated signal to the processor 110. It will be appreciated for a person having ordinary knowledge in the art that the sensor may be included or excluded in accordance with the performance of the terminal apparatus 100.

The storage 170 may store data without limitation under control of the processor 110.

The storage 170 may store a program for controlling the terminal apparatus 100, an application provided by a manufacturer or downloaded from the exterior, a related graphic user interface (GUI), images for providing the GUI, user information, a document, a database, and the like data.

According to an exemplary embodiment, the storage 170 may include a ROM and a RAM.

According to still another exemplary embodiment, the connector cap 140 may be integrated into a packaging material for the terminal apparatus 100 (e.g. a packaging case or the like) or coupled to the packaging material, so that the packaging material can serve as the connector cap 140. In this case, the connector cap 140 is naturally separated from the connector 130 while a user opens the packaging material to unpack a product after making a purchase of the product, thereby improving a user's convenience.

Below, operations for power supply control in the terminal apparatus according to an exemplary embodiment will be described with reference to accompanying drawings.

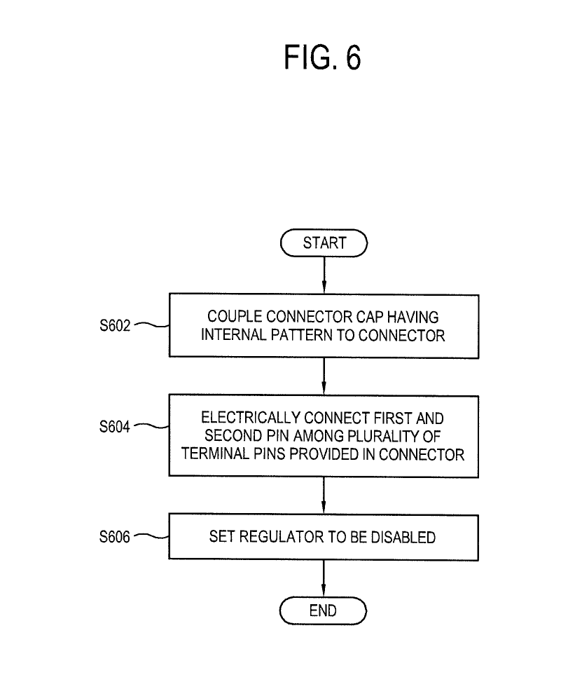

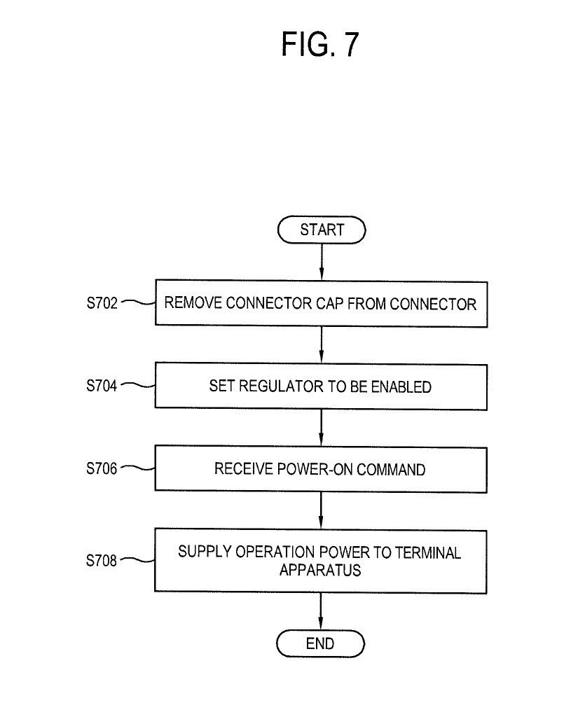

FIG. 6 and FIG. 7 are flowcharts of a power controlling method of the terminal apparatus 100 according to exemplary embodiments.

As shown in FIG. 6, the terminal apparatus 100 to be released senses that the connector cap 140 having a predetermined pattern is coupled to the inside of the connector 130 (S602). The connector 130 may include a plurality of terminal pins for receiving the charging power from the external charging source to charge the battery 121 in the terminal apparatus 100.

In response to the sensing in the operation S602, the first pin and the second pin are electrically connected among the plurality of terminal pins of the connector 130 (S604). Specifically, the connector cap 140 has a predetermined pattern 141 so that the first pin and the second pin (e.g. pin Nos. 2 and 3) can be electrically connected as shown in FIG. 3. Further, the coupling in the operation S602 forms a kind of closed circuit where an electric current flows from the first pin (No. 2) to the second pin (No. 3) via the pattern 141 as shown in FIG. 4.

Since a high signal is applied to the enable terminal EN of the regulator 125 by the electric connection in the operation S604, the regulator 125 becomes inactivated, i.e. disabled (S606). Therefore, as shown in FIG. 4, the inactivated regulator 125 cuts off power not to be supplied to the processor 110.

By the operations S602 to S604, the terminal apparatus 100 according to an exemplary embodiment is released and distributed with the cap 140 coupled to the connector 130 so that the regulator 125 interposed in between the battery 121 and the processor 110 can cut off the power not to be being supplied to the processor 110, thereby preventing the standby current from being consumed in the processor 110.

Thus, a user makes a purchase of the terminal apparatus 100 coupling with the connector cap 140 as shown in FIG. 6.

To use the purchased terminal apparatus 100, a user removes the connector cap 140 coupled to the connector 130 (S702) as shown in FIG. 7. Here, the connector cap to be removed is coupled in the operation S602 of FIG. 6, and has the pattern 141 for electrically connecting the first pin and the second pin (e.g. pin Nos. 2 and 3) of the connector 130.

In response to the removal of the cap 140 in the operation S702, the first pin and the second pin (e.g. pin Nos. 2 and 3) are electrically disconnected, and a low signal is applied to the enable terminal EN of the regulator 125, thereby setting the regulator 125 to be inactivated, i.e. enabled (S704). Thus, power is supplied to some blocks of the processor 110 through the activated regulator 125. Here, some blocks of the processor 110, to which the power is supplied, are elements needed for minimum operations and may for example include the switching block 113 described with reference to FIG. 5.

Then, a user makes an input of the power-on command to the terminal apparatus 100 (S706). Here, the power-on command may be received by the user's input described with reference to FIG. 5.

In response to the power-on command in the operation S706, the switch in the switching block 113 is turned on, and thus the operation power is supplied to the main block 111 of the processor 110 in the terminal apparatus 100 (S708).

In accordance with the operations S702 to S708, a user can directly use the terminal apparatus 100, in which the current of the battery 121 is not consumed during distribution after release, by just removing the cap 140 from the connector 130.

The features of the foregoing exemplary embodiments may be partially or entirely coupled or combined, and technically variously interworked and driven as fully appreciated by those skilled in the art. Further, the foregoing exemplary embodiments may be materialized independently of each other or realized to interwork together.

According to the exemplary embodiments, the connector cap 140 is coupled to the connector 130 having the plurality of terminal pins, and thus two pins not used in charging are electrically connected to cut off power not to be supplied to the processor 110, thereby preventing a standby current from being consumed while the terminal apparatus 100 is released and distributed.

Therefore, the battery 121 is not discharged even though the terminal apparatus 100 is neglected for a long time after release, thereby preventing the battery 121 and the apparatus 100 from being damaged.

Further, a user can directly use the terminal apparatus 100 without separately charging the battery 121 by just removing the cap 140 after making a purchase of the terminal apparatus 100, and thus the terminal apparatus 100 is more convenient for a user.

By the way, the foregoing exemplary embodiments may be realized in a recording medium for storing a computer-readable program and/or a computer-readable program stored in the recording medium. The computer-readable recording medium may include a storage medium for storing data readable by a computer system. The program is transmitted and received through a transfer medium materialized by a wired/wireless network to which the computer system is connected.

The foregoing exemplary embodiments may be realized by hardware and combination between hardware and software. As the hardware, a processor 110 may include a CPU, an AP or a MICOM for executing software, i.e. a computer program loaded to the RAM. The computer program is stored in a nonvolatile memory, and the nonvolatile memory may include a hard disk drive, a flash memory, a ROM, CD-ROMs, magnetic tapes, a floppy disc, an optical storage, a data transfer apparatus using Internet, etc., but not limited thereto. The nonvolatile memory is a kind of computer-readable recording medium in which a program readable by a computer is recorded.

The computer program may be a code that is read and executed by the CPU, and may include codes for performing the operations of the processor 110 such as the operations S602 to S606 as shown in FIG. 6 and the operations S702 to S708 as shown in FIG. 7.

The computer program may be included in an operating system provided in the terminal 100 or software including a program/application and/or software interfacing with an external apparatus.

Although exemplary embodiments have been shown and described, it will be appreciated by those skilled in the art that changes may be made to these exemplary embodiments without departing from the principles and spirit of the disclosure, the scope of which is defined in the appended claims and their equivalents.

What is claimed is:

1. A terminal apparatus, comprising:
a rechargeable battery configured to supply operation power for the terminal apparatus;
a regulator configured to regulate and output the operation power supplied from the rechargeable battery at a predetermined level;
a connector comprising a plurality of terminal pins and configured to receive charging power for the rechargeable battery from an external charging source through the plurality of terminal pins; and
a connector cap configured to be coupled with the connector and including a pattern for electrically connecting a first pin and a second pin among the plurality of terminal pins such that when the connector cap is coupled with the connector, an electric current of the rechargeable battery is prevented from being consumed.

2. The terminal apparatus according to claim 1, wherein the first pin and the second pin among the plurality of terminal pins are electrically connected when the connector cap is coupled with the connector, and the regulator becomes inactivated.

3. The terminal apparatus according to claim 2, further comprising a processor configured to receive the operation power from the rechargeable battery through the regulator,
wherein
the regulator is provided in between the rechargeable battery and the processor, and
when the regulator is inactivated, the regulator cuts off the operation power from the processor.

4. The terminal apparatus according to claim 3, wherein
the regulator becomes activated when the first pin and the second pin among the plurality of terminal pins are electrically disconnected in response to removal of the connector cap from the connector, and
the operation power is supplied to at least a part of the processor through the regulator.

5. The terminal apparatus according to claim 4, wherein
the processor comprises a switching block to be turned on in response to a user's input and a main block to perform operations, and
the operation power is supplied to the switching block in response to the activation of the regulator.

6. The terminal apparatus according to claim 2, wherein the first pin among the plurality of terminal pins is connected to the rechargeable battery, and the second pin among the plurality of terminal pins is connected to an enable terminal of the regulator.

7. The terminal apparatus according to claim 1, wherein
the connector comprises a universal serial bus (USB) connector, and
the connector cap comprises a coupling hole or a coupling projection to be inserted in and engaged with the USB connector.

8. The terminal apparatus according to claim 1, wherein
the plurality of terminal pins comprises a power pin and a ground pin to receive the charging power from the external charging source, and
the first pin and the second pin among the plurality of terminal pins are not used in receiving the charging power from the external charging source and are electrically connected by the pattern when the connector cap is coupled with the connector.

9. A power controlling method of a terminal apparatus that receives operation power from a rechargeable battery, the method comprising:
sensing that a connector cap having a pattern for electrically connecting a first pin and a second pin among a plurality of terminal pins provided in a connector is coupled to the connector, the connector being configured to receive charging power for the rechargeable battery from an external charging source through the plurality of terminal pins; and
inactivating a regulator for regulating and outputting the operation power supplied from the rechargeable battery at a predetermined level, in response to the connector and the connector cap being coupled.

10. The method according to claim 9, wherein the regulator is provided in between the rechargeable battery and a processor, and inactivating the regulator cuts off the operation power from the processor.

11. The method according to claim 10, further comprising:
sensing that the connector cap is removed from the connector;
activating the regulator when the first pin and the second pin are electrically disconnected in response to the connector cap being removed from the connector; and
supplying the operation power to at least a part of the processor through the regulator.

12. An input apparatus for a display apparatus, the input apparatus comprising:
a user input interface configured to receive a user input;
a rechargeable battery configured to supply operation power for the terminal apparatus;
a regulator configured to regulate and output the operation power supplied from the rechargeable battery at a predetermined level;
a connector comprising a plurality of terminal pins and configured to receive charging power for the rechargeable battery from an external charging source through the plurality of terminal pins; and
a connector cap configured to be coupled with the connector and including a pattern for electrically connecting a first pin and a second pin among the plurality of terminal pins such that when the connector cap is coupled with the connector, an electric current of the rechargeable battery is prevented from being consumed.

13. The input apparatus according to claim 12, wherein the first pin and the second pin among the plurality of terminal pins are electrically connected when the connector cap is coupled with the connector, and the regulator becomes inactivated.

14. The input apparatus according to claim 13, further comprising a processor configured to receive the operation power from the rechargeable battery through the regulator,
wherein
the regulator is provided in between the rechargeable battery and the processor, and
when the regulator is inactivated, the regulator cuts off the operation power from the processor.

15. The input apparatus according to claim 14, wherein
the regulator becomes activated when the first pin and the second pin among the plurality of terminal pins are electrically disconnected in response to removal of the connector cap from the connector, and
the operation power is supplied to at least a part of the processor through the regulator.

16. The input apparatus according to claim 13, wherein the first pin among the plurality of terminal pins is connected to the rechargeable battery, and the second pin among the plurality of terminal pins is connected to an enable terminal of the regulator.

17. The input apparatus according to claim 12, wherein
the connector comprises a universal serial bus (USB) connector, and
the connector cap comprises a coupling hole or a coupling projection to be inserted in and engaged with the USB connector.

18. The input apparatus according to claim 12, wherein
the plurality of terminal pins comprises a power pin and a ground pin to receive the charging power from the external charging source, and
the first pin and the second pin among the plurality of terminal pins are not used in receiving the charging power from the external charging source and are electrically connected by the pattern when the connector cap is coupled with the connector.
